(19) United States
(12) Patent Application Publication
(10) Pub. No.: US 2023/0422349 A1
(43) Pub. Date: Dec. 28, 2023

(54) CONDUCTIVE MEMBER AND HEATER

(71) Applicant: FUJIFILM Corporation, Tokyo (JP)

(72) Inventors: Morihito IKEDA, Kanagawa (JP); Hideki YASUDA, Kanagawa (JP)

(73) Assignee: FUJIFILM Corporation, Tokyo (JP)

(21) Appl. No.: 18/462,338

(22) Filed: Sep. 6, 2023

Related U.S. Application Data
(63) Continuation of application No. PCT/JP2022/009035, filed on Mar. 3, 2022.

(30) Foreign Application Priority Data
Mar. 10, 2021 (JP) 2021-037979
Jul. 30, 2021 (JP) 2021-125199
Aug. 20, 2021 (JP) 2021-134601

(51) Int. Cl. H05B 3/03

(52) U.S. Cl. CPC H05B 3/03

(57) ABSTRACT

A conductive member (11) includes an electrode pad (14) for applying a voltage to a conductive film (13), in which a plurality of non-conductive portions (16) that are arranged to form a regular repeating pattern are formed in the conductive film (13), each of the plurality of non-conductive portions (16) include a plurality of base units having an elongated shape that are connected to each other at a connection point (C1) and extend from the connection point (C1) in different directions, and a direction in which a line segment that connects the connection points (C1) of the two non-conductive portions (16) closest to each other among the plurality of non-conductive portions (16) extends is different from each of the directions in which the plurality of base units extend.

### CROSS-REFERENCE TO RELATED APPLICATIONS

This application is a Continuation of PCT International Application No. PCT/JP2022/009035 filed on Mar. 3, 2022, which claims priority under 35 U.S.C. § 119(a) to Japanese Patent Application No. 2021-037979 filed on Mar. 10, 2021, Japanese Patent Application No. 2021-125199 filed on Jul. 30, 2021, and Japanese Patent Application No. 2021-134601 filed on Aug. 20, 2021. The above applications are hereby expressly incorporated by reference, in their entirety, into the present application.

### BACKGROUND OF THE INVENTION

### 1. Field of the Invention

The present invention relates to a conductive member having transmittance with respect to an electromagnetic wave in a specific frequency band and a heater including the conductive member.

### 2. Description of the Related Art

In the related art, a sensor, a communication apparatus, or the like using an electromagnetic wave such as a millimeter wave or a microwave are generally used. This apparatus is mounted on, for example, an automobile, and a protective cover is provided around the apparatus in many cases. It is known that snow accretion or ice accretion on the cover or fogging or the like caused by water vapor causes erroneous detection in the sensor or communication failure in the communication apparatus disposed inside the cover. In order to remove snow accretion, ice accretion, and fogging, for example, a heat generating member disclosed in WO2017/163830A is developed. The heat generating member disclosed in WO2017/163830A includes: a three-dimensional structure with a plated layer; and a conductive laminate including a metal layer disposed on the plated layer, in which the metal layer functions as a heating wire.

In addition, it is known that an electromagnetic wave in a frequency band different from the frequency band of the electromagnetic wave that is transmitted and received by the sensor, the communication apparatus, or the like causes erroneous detection in the sensor and communication crosstalk or the like in the communication apparatus. In order to suppress erroneous detection in the sensor and communication crosstalk or the like, for example, a structure of a metal mesh disclosed in Vyachesla V. Komarov, Valery P. Meschanov, “Transmission properties of metal mesh filters at 90 GHz”, Journal of Computational Electronics, Feb. 28, 2019, 18:696-704 is known. In the metal mesh disclosed in Vyachesla V. Komarov, Valery P. Meschanov, “Transmission properties of metal mesh filters at 90 GHz”, Journal of Computational Electronics, Feb. 28, 2019, 18:696-704, a plurality of cross-shaped non-conductive portions arranged in a lattice form in two directions orthogonal to each other are formed. Due to the plurality of non-conductive portions, an electromagnetic wave in a frequency band corresponding to the size of the cross shape is likely to transmit the metal mesh, and an electromagnetic wave in the other frequency band is shielded.

### SUMMARY OF THE INVENTION

However, the heat generating member disclosed in WO2017/163830A cannot allow transmission of only an electromagnetic wave in a specific frequency band. Therefore, it is difficult to simultaneously achieve a heat generation function and a function of allowing transmission of only an electromagnetic wave in a specific frequency band.

In addition, the present inventors found that, in a case where the metal mesh disclosed in Vyachesla V. Komarov, Valery P. Meschanov, “Transmission properties of metal mesh filters at 90 GHz”, Journal of Computational Electronics, Feb. 28, 2019, 18:696-704 is energized to generate heat, a current intensively flows through the plurality of non-conductive portions such that local heat generation occurs and deterioration of the metal mesh such as oxidation of the metal mesh occurs in the local portion. In order to avoid the concentration of the current, a method of widening a gap between the plurality of non-conductive portions can be considered. However, in a case where the gap is widened, the transmittance of an electromagnetic wave having a specific frequency band corresponding to the size of the non-conductive portion decreases, and there is a problem in that the function of allowing transmission of only the electromagnetic wave in the specific frequency band is not sufficiently exhibited.

The present invention has been made in order to solve the above-described problems, and an object thereof is to provide a conductive member where local deterioration can be suppressed while simultaneously achieving a heat generation function and a function of allowing transmission of an electromagnetic wave in a specific frequency band.

In order to achieve the above-described object, according to the present invention, there is provided a conductive member where a conductive film is formed, the conductive member comprising: an electrode pad for applying a voltage to the conductive film, in which a plurality of non-conductive portions that are arranged to form a regular repeating pattern are formed in the conductive film, each of the plurality of non-conductive portions includes a plurality of base units having an elongated shape that are connected to each other at a connection point and extend from the connection point in different directions, and a direction in which a line segment that connects the connection points of two non-conductive portions closest to each other among the plurality of non-conductive portions extends is different from each of the directions in which the plurality of base units extend.

It is preferable that a pair of the electrode pads are connected to both end parts of the conductive film, and it is preferable that, in the conductive film, the non-conductive portion is disposed on any path that connects the pair of electrode pads to each other along a surface of the conductive film.

In addition, the conductive film can extend in a planar shape. In this case, the non-conductive portion can be disposed on any path that linearly connects the pair of electrode pads to each other along the surface of the conductive film.

The non-conductive portion can configured by four base units. In this case, it is preferable that the four base units are connected to each other to form a cross shape at the connection point.

In this case, a distance between the two non-conductive portions closest to each other among the plurality of non-conductive portions is preferably 20% or more and 50% or less and more preferably 30% or more and 40% or less with respect to a distance between the connection points of the two non-conductive portions.

It is preferable that the conductive member further comprises a plurality of conductive wirings that form a mesh shape, and it is preferable that the conductive film is formed of the plurality of conductive wirings.

In this case, a direction in which at least one of the base units of the non-conductive portion extends may be the same as or different from one of directions in which the plurality of conductive wirings extend.

It is preferable that the electrode pad has a width that is 10 or more times wider than a line width of the conductive wiring.

The conductive member may further comprise: a plurality of dummy wirings that are disposed on extension lines of the plurality of conductive wirings and are electrically insulated from the plurality of conductive wirings in the non-conductive portion.

The conductive film can have a shape along a curved surface.

In addition, the conductive film has preferably a sheet resistance of 0.1 Ω/□ or more and 10.0 Ω/□ or less and more preferably a sheet resistance of 0.3 Ω/□ or more and 3.0 Ω/□ or less.”

It is preferable that the base unit has a width of 0.1 mm or more and 1000.0 mm or less in a direction in which the base unit extends.

According to the present invention, there is provided a heater comprising the above-described conductive member.

The conductive member according to the present invention comprises an electrode pad for applying a voltage to a conductive film, in which a plurality of non-conductive portions that are arranged to form a regular repeating pattern are formed in the conductive film, each of the plurality of non-conductive portions includes a plurality of base units having an elongated shape that are connected to each other at a connection point and extend from the connection point in different directions, and a direction in which a line segment that connects the connection points of two non-conductive portions closest to each other among the plurality of non-conductive portions extends is different from each of the directions in which the plurality of base units extend. Therefore, local deterioration can be suppressed while simultaneously achieving a heat generation function and a function of allowing transmission of an electromagnetic wave in a specific frequency band.

### BRIEF DESCRIPTION OF THE DRAWINGS

FIG. 1 is a cross-sectional view schematically showing a part of a conductive member according to a first embodiment of the present invention.

FIG. 2 is a plan view showing the conductive member according to the first embodiment of the present invention.

FIG. 3 is an enlarged schematic diagram showing a conductive mesh according to the first embodiment of the present invention.

FIG. 4 is a diagram showing a non-conductive portion according to the first embodiment of the present invention.

FIG. 5 is a diagram showing three non-conductive portions adjacent to each other in the first embodiment of the present invention.

FIG. 6 is a diagram showing a modification example of the non-conductive portion according to the first embodiment of the present invention.

FIG. 7 is a diagram showing another modification example of the non-conductive portion according to the first embodiment of the present invention.

FIG. 8 is a plan view showing the conductive member according to the modification example of the first embodiment of the present invention.

FIG. 9 is a diagram showing a non-conductive portion according to a second embodiment of the present invention.

FIG. 10 is an enlarged view showing a gap according to the second embodiment of the present invention.

FIG. 11 is a plan view showing a conductive member according to a third embodiment of the present invention.

FIG. 12 is a plan view showing a conductive member according to Comparative Example 1.

### DESCRIPTION OF THE PREFERRED EMBODIMENTS

Hereinafter, a conductive member according to the present invention will be described in detail based on a preferred embodiment shown in the accompanying drawings.

The drawings described below are exemplary drawings for describing the present invention, and the present invention is not limited to the drawings described below.

In the following description, a numerical range indicated by the expression “to” includes numerical values described on both sides. For example, in a case where ε is a numerical value α to a numerical value β, the range ε is a range including the numerical value α and the numerical value β, which is expressed by a mathematical symbol α≤ε≤β.

Unless specified otherwise, the meaning of an angle such as “parallel” or “orthogonal” includes a case where an error range is generally allowable in the technical field.

In addition, the meaning of “the same” includes a case where an error range is generally allowable in the technical field.

In this specification, “(meth)acrylate” denotes either or both of acrylate and methacrylate, and “(meth)acryl” denotes either or both of acryl and methacryl. In addition, “(meth)acryloyl” denotes either or both of acryloyl and methacryloyl.

Unless specified otherwise, being transparent with respect to visible light represents that a visible light transmittance in a visible wavelength range of 380 nm to 800 nm is 40% or more, preferably 80.0% or more, and more preferably 90.0% or more. In the following description, unless specified otherwise, being transparent represents being transparent with respect to visible light.

The visible light transmittance is measured using “Plastics—Determination of Total Luminous Transmittance and Reflectance” defined by Japanese Industrial Standards (JIS) K 7375:2008.

### First Embodiment

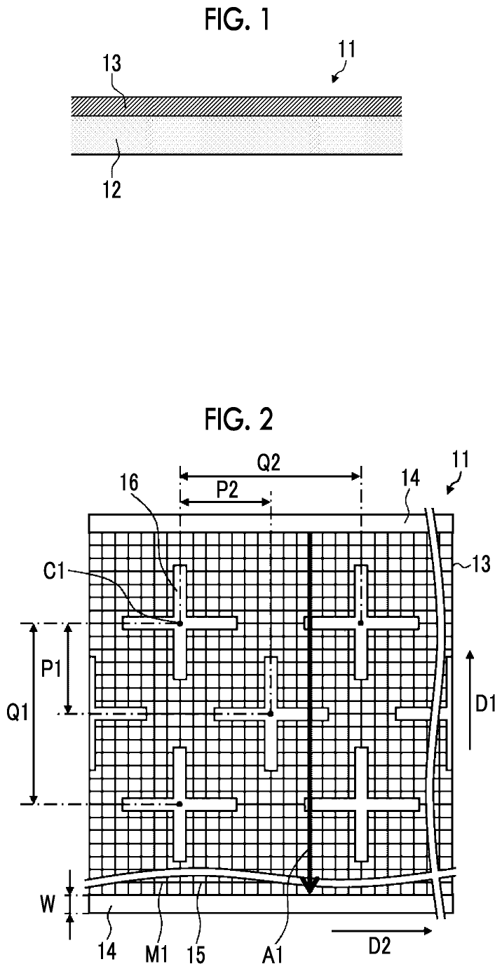

FIG. 1 is a conductive member 11 according to an embodiment of the present invention. The conductive member 11 is a film-like member and includes an insulating transparent substrate 12 and a conductive film 13 that is formed on a single surface of the substrate 12.

The conductive film 13 is transparent and has a visible light transmittance of, for example, 75.0% or more.

As shown in FIG. 2, the conductive member 11 includes a pair of electrode pads 14 that are connected to opposite ends of the conductive film 13 to apply a voltage to the conductive film 13. Each of the electrode pads 14 has a rectangular shape, and the electrode pads 14 are disposed such that long sides thereof face each other. In addition, each of the pair of electrode pads 14 has a width W in a short side direction orthogonal to the long side.

Hereinafter, for convenience of description, a direction from one electrode pads 14 toward another electrode pads 14 will be referred to as a first direction D1, and a direction orthogonal to the first direction D1 will be referred to as a second direction D2.

The conductive film 13 is formed of a plurality of conductive wirings 15 that extend in the first direction D1 and the second direction D2. In addition, a conductive mesh M1 is formed of the plurality of conductive wirings 15.

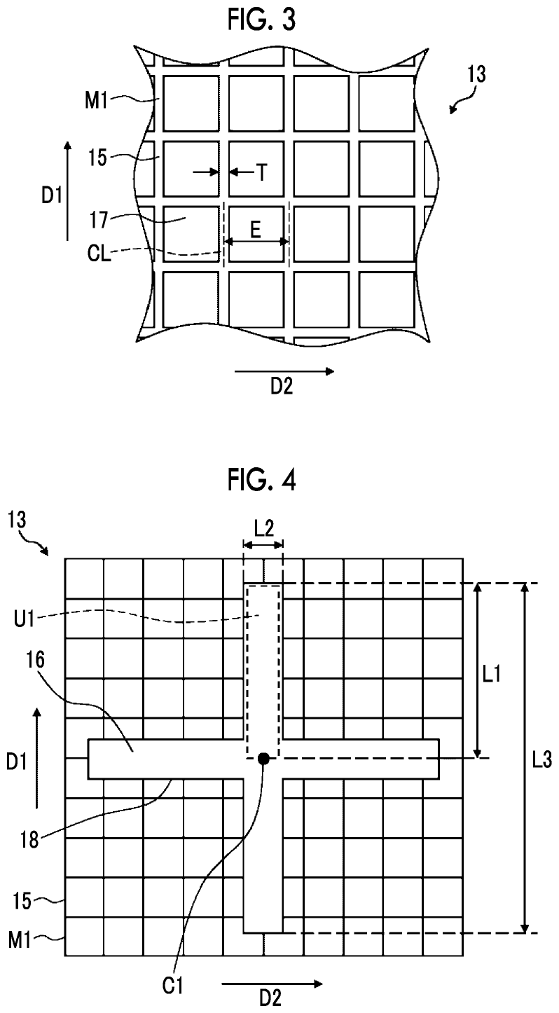

As shown in FIG. 3, the plurality of conductive wirings 15 have a line width T and are disposed at a pitch E defined as a distance between center lines CL of the conductive wirings 15.

In addition, the conductive mesh M includes a plurality of square opening portions 17 and form a so-called square grid.

The line width T of the conductive wirings 15 is not particularly limited, and the upper limit thereof is preferably 1000.00 μm or less, more preferably 500.00 μm or less, and still more preferably 300.00 μm or less. The lower limit of the line width T is 1.00 μm or more and more preferably 3.00 μm or more. In a case where the line width T is in the above-described range, the conductive mesh M can be made to have a high conductivity. In addition, from the viewpoint of conductivity, the thickness of the conductive wirings 15 can be set to be 0.01 μm or more and 200.00 μm or less, and the upper limit thereof is preferably 30.00 μm or less, more preferably 20.00 μm or less, still more preferably 9.00 μm or less, and still more preferably 5.00 μm or less. The lower limit of the thickness of the conductive wirings 15 is preferably 0.01 μm or more, more preferably 0.10 μm or more, and still more preferably 0.5 μm or more.

A sheet resistance of the conductive film 13 formed of the plurality of conductive wirings 15 is preferably 0.1 Ω/□ or more and 10.0 Ω/□ or less and more preferably 0.3 Ω/□ or more and 3.0 Ω/□ or less. This way, the conductive film 13 has a low sheet resistance of 10.0 Ω/□ or less. Therefore, the conductive film 13 has a high heater performance of generating a large amount of heat under a condition where a voltage is limited, and has a high electromagnetic wave transmittance. In addition, the conductive film 13 has a resistance value of 0.10 Ω/□ or more. Therefore, the conductive film 13 has a high heater performance of generating a large amount of heat under a condition where a current is limited.

In addition, as shown in FIG. 2, in the conductive film 13, a plurality of cross-shaped non-conductive portions 16 arranged in the same direction to form a regular repeating pattern are formed.

As shown in FIG. 4, the non-conductive portion 16 is a portion that is surrounded by an edge portion 18 formed of the conductive wirings 15 and having a cross shape and where the conductive wirings 15 are not present, and the inside of the non-conductive portion 16 is not electrically conductive. In addition, the non-conductive portion 16 is configured by one end parts of four base units U1 having a rectangular shape being connected to each other at a connection point C1 that is the center of the cross shape. The four base units U1 extend from the connection point C1 in different directions including the first direction D1, a direction opposite to the first direction D1, the second direction D2, and a direction opposite to the second direction D2.

In the example of FIG. 4, each of the four base units U1 in the non-conductive portion 16 has a rectangular shape, has a width L1 in a direction of a long side, and has a width L2 in a direction of a short side. In addition, the non-conductive portion 16 has a width L3 having a length that is two times the width L1 of the base unit U1 in the first direction D1 and the second direction D2.

Here, the non-conductive portion 16 allows transmission of an electromagnetic wave in a specific frequency band corresponding to the size thereof, that is, the width L2 and the width L3 (width L1). Therefore, the size of the non-conductive portion 16 is designed depending on the frequency band of the electromagnetic wave that can transmit through the non-conductive portion 16. For example, in a case where an electromagnetic wave in a frequency band called a millimeter wave centering on 76.5 GHz transmits through the non-conductive portion 16, it is preferable that the width L2 is designed as 120 μm and the width L3 is designed as 1330 μm. Note that the width L2 and the width L3 can be appropriately adjusted because they also depend on a positional relationship between the plurality of non-conductive portions.

This way, since the non-conductive portions 16 are formed in the conductive film 13, the conductive film 13 allows transmission of an electromagnetic wave in a specific frequency band and shields an electromagnetic wave in the other frequency band.

In the example shown in FIG. 2, the plurality of non-conductive portions 16 are alternately arranged such that two non-conductive portions 16 closest to each other are shifted at a pitch P1 in the first direction D1 and at a pitch P2 in the second direction D2. The plurality of non-conductive portions 16 alternately arranged as described above. Therefore, the non-conductive portions 16 are arranged in the first direction D1 at an interval of a pitch Q1 having a length that is two times the pitch P1, and are arranged in the second direction D2 at an interval of a pitch Q2 having a length that is two times the pitch P2.

Here, the pitch P1 refers to the distance in the first direction D1 between the connection points C1 of two non-conductive portions 16 closest to each other, and the pitch P2 refers to the distance in the second direction D2 between the connection points C1 of two non-conductive portions 16 closest to each other. In addition, the pitch Q1 refers to the distance between the connection points C1 of two non-conductive portions 16 disposed adjacent to each other in the first direction D1, and the pitch Q2 refers to the distance between the connection points C1 of two non-conductive portions 16 disposed adjacent to each other in the second direction D2.

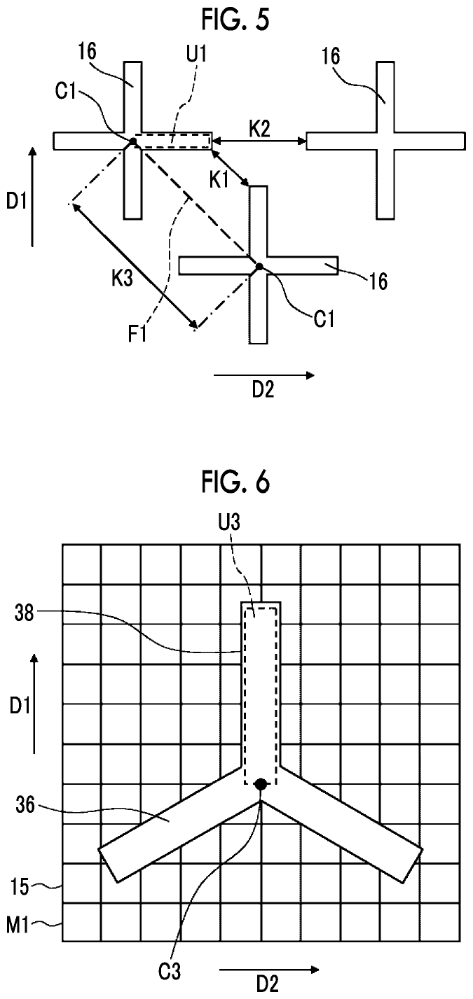

In addition, as shown in FIG. 5, a direction in which a line segment F1 that connects the connection points C1 of two non-conductive portions 16 closest to each other among the plurality of non-conductive portions 16 extends is different from the directions in which the four base units U1 of each of the plurality of non-conductive portions 16 extend, that is, the first direction D1, the direction opposite to the first direction D1, the second direction D2, and the direction opposite to the second direction D2.

Here, in general, in a case where the transmission of the electromagnetic wave in the specific frequency band corresponding to the size of the non-conductive portion is allowed and the electromagnetic wave in the other frequency band is shielded by the disposing the plurality of non-conductive portions, it is known that the distance between the connection points of non-conductive portions adjacent to each other needs to be set to an appropriate value corresponding to the frequency band of the electromagnetic wave to be transmitted.

In addition, the present inventor found that, in a case where a voltage is applied to the conductive member where the plurality of non-conductive portions are formed such that the conductive member generates heat, as the distance between the non-conductive portions is designed to be narrower, a current intensively flows through the non-conductive portions such that local heat generation is likely to occur. Accordingly, in a case where the distance between the non-conductive portions is designed to be widened to avoid the concentration of the current, there is a problem in that the function of allowing the transmission of the electromagnetic wave in the specific frequency band corresponding to the size of the non-conductive portion deteriorates.

In the conductive member 11 according to the first embodiment of the present invention, as shown in FIG. 5, the plurality of non-conductive portions 16 are arranged such that the direction in which the line segment F1 that connects the connection points C1 of two non-conductive portions 16 closest to each other among the plurality of non-conductive portions 16 extends is different from each of the directions in which the plurality of base units U1 of each of the non-conductive portions 16 extend. Therefore, while designing the distance between the connection points C1 of the non-conductive portions 16 to the appropriate value corresponding to the frequency band of the electromagnetic wave to be transmitted through the conductive member 11, a distance K1 between two non-conductive portions 16 closest to each other and a distance K2 between two non-conductive portions 16 adjacent to each other in the first direction D1 or the second direction D2 can be designed to be wide such that a current does not significantly concentrate.

As a result, an increase in the density of the current flowing through two non-conductive portions 16 close to each other can be suppressed without deterioration of the function of allowing the transmission of the electromagnetic wave in the specific frequency band.

Here, as shown in FIG. 5, by designing the distance K1 between two non-conductive portions 16 closest to each other among the plurality of non-conductive portions 16 to be 20% or more and 50% or less with respect to a distance K3 between the connection points C1 of the two non-conductive portions 16, an increase in the density of the current flowing through the two non-conductive portions 16 close to each other can be suppressed. By designing the distance K1 to be 30% or more and 40% or less with respect to the distance K3, an increase in the density of the current flowing through the two non-conductive portions 16 close to each other can be further suppressed.

As described above, in the conductive member 11 according to the first embodiment of the present invention, the plurality of non-conductive portions 16 are arranged such that the direction in which the line segment F1 that connects the connection points C1 of two non-conductive portions 16 closest to each other among the plurality of non-conductive portions 16 extends is different from the directions in which the four base units U1 of each of the non-conductive portions 16 extend. Therefore, the local deterioration can be suppressed while simultaneously achieving the heat generation function and the function of allowing the transmission of the electromagnetic wave in the specific frequency band.

In addition, as shown in FIG. 2, in the conductive member 11, in the conductive film 13, the non-conductive portion 16 is disposed on any path A1 that linearly connects the pair of electrode pads 14 to each other along a surface of the conductive film 13 in the first direction D1. Therefore, it is considered that a current flowing through the conductive film 13 from one electrode pad 14 to another electrode pad 14 moves while bypassing the plurality of non-conductive portions 16 relatively uniformly. This way, in the conductive member 11, by disposing the non-conductive portion 16 on any path A1 that connects the pair of electrode pads 14 in the first direction D1, that is, on any shortest path that linearly connect the pair of electrode pads 14 on the surface of the conductive film 13, the local flowing of a current through the conductive film 13 can be further suppressed.

In addition, although not shown in the drawing, a heater can be configured by the conductive member 11 according to the first embodiment of the present invention and a power supply device for applying a voltage to the conductive film 13 in the conductive member 11. This heater is particularly useful in a case where the heater is disposed to cover a sensor, a communication apparatus, or the like using an electromagnetic wave such as a so-called millimeter wave or a microwave that is provided in, for example, an automobile.

For example, in a case where snow accretion, ice accretion, or the like occurs around the sensor, the communication apparatus, or the like, it is known that erroneous detection in the sensor or communication failure in the communication apparatus is likely to occur. In addition, in a case where an electromagnetic wave in a frequency band different from an electromagnetic wave that is transmitted and received by the sensor, the communication apparatus, or the like is present around the sensor, the communication apparatus, or the like, it is also known that crosstalk between the electromagnetic waves in the different frequency bands occurs such that the erroneous detection or the communication failure is likely to occur. With the heater including the conductive member 11 according to the first embodiment of the present invention, snow accretion, ice accretion or the like caused by the heater can be removed, the transmission of the electromagnetic wave in the frequency band corresponding to the size of the plurality of non-conductive portions 16 in the conductive member 11 can be allowed, and an electromagnetic wave in the other frequency band can be shielded. Therefore, the effect of snow accretion, ice accretion, or the like can be suppressed, and erroneous detection, communication failure, or the like in the sensor, the communication apparatus, or the like can be suppressed. Further, the heater includes the conductive member 11 according to the first embodiment of the present invention, and the occurrence of local deterioration in the conductive film 13 caused by heat generation can be also be suppressed. Therefore, the durability is excellent.

It is preferable that the pair of electrode pads 14 have the width W that is 10 or more times wider than the line width T of the conductive wiring 15. This way, by designing the width W of the electrode pad 14 to be wide, voltage loss caused by contact resistance in a connecting part between the electrode pad 14 and a power supply (not shown) and voltage loss in the electrode pad 14 can be reduced. Therefore, unnecessary energy loss in the electrode pad 14 can be suppressed.

In addition, FIG. 1 shows that the conductive film 13 has a shape along a plane. However, the conductive film 13 can also have a shape along a curved surface. For example, by forming the conductive film 13 on the substrate 12 having a curved surface, the conductive film 13 can be formed to have a shape along the curved surface shape of the substrate 12. Examples of the curved surface shape include a shape along a surface of any three-dimensional shape such as a sphere, a cylinder, or a cone.

In a case where the conductive film 13 has a shape along a curved surface, it is preferable that the non-conductive portion 16 is disposed on any path that connects the pair of electrode pads 14 connected to both end parts of the conductive film 13 on the surface of the conductive film 13. Here, the path that connects the electrode pads 14 along the surface of the conductive film 13 refers to a path that is orthogonal to an edge portion of the pair of electrode pads 14 facing each other and advances from one electrode pad 14 to another electrode pad 14 along the curved surface shape of the conductive film 13. It is preferable that this path connects the pair of electrode pads 14 by the shortest distance.

By disposing the plurality of non-conductive portions 16 on the conductive film 13, the local flowing of a current through the conductive film 13 can be further suppressed. In addition, the conductive film 13 can also have a shape along a more complicated three-dimensional surface. Examples of the complicated three-dimensional shape include an emblem of an automobile, a radome of a radar, a front cover of a radar, a headlamp cover of an automobile, an antenna, and a reflector. By disposing the conductive member 11 according to the embodiment of the present invention along the three-dimensional shape, for example, the conductive member 11 can be disposed along an emblem of an automobile, and a radar can be mounted in the emblem.

In addition, in a case where the design of a member covered with the conductive member 11 is desired to be visible to an external observer, for example, in a case where the conductive member 11 is disposed along an emblem of an automobile, it is desirable that the conductive member 11 has transparency. In this case, in order to make the presence of the conductive mesh M1 inconspicuous, the upper limit of the pitch E of the conductive mesh M1 is preferably 800.00 μm or less, more preferably 600.00 μm or less, and still more preferably 400.00 μm or less. In addition, the lower limit of the pitch E is preferably 5.00 μm or more, more preferably 30.00 μm or more, and still more preferably 80.00 μm or more.

In addition, in order to for the conductive member 11 to have a visible light transmittance of 75.0% or more, an opening ratio of the conductive mesh M is preferably 75% or more and more preferably 80% or more. Here, the opening ratio of the conductive mesh M refers to the ratio of transmitting portions excluding the conductive wirings 15 to the region of the conductive mesh M. That is, the opening ratio corresponds to a ratio of the total area of the plurality of opening portions 17 to the total area of the conductive mesh M.

The shape of the plurality of opening portions 17 in the conductive mesh M is not limited to a square shape. For example, a triangle such as a regular triangle, an isosceles triangle, or a right triangle, a quadrangle such as a square, a rectangle, a parallelogram, or a trapezoid, a regular polygon such as a (regular) hexagon or a (regular) octagon, a circle, an ellipse, or a star shape can be adopted, or a geometric figure as a combination of the above-described shapes can also be adopted.

In addition, in the above description, the conductive film 13 is formed of the plurality of conductive wirings 15. However, the present invention is not particularly limited to this configuration. For example, the conductive film 13 may be formed of a film of a so-called transparent conductive oxide such as indium tin oxide (ITO), a metal, or the like, and the conductive film 13 may be formed of a surface of the film.

In this case, the non-conductive portion 16 is formed, for example, by cutting the film of the transparent conductive oxide, the metal, or the like in a cross shape. By the non-conductive portion 16 formed as described above, the electromagnetic wave in the frequency band corresponding to the size of the non-conductive portion 16 transmits through the conductive member 11, and an electromagnetic wave in the other frequency band is shielded. In addition, in a case where a voltage is applied to the conductive member 11, a current flowing from one electrode pad 14 to another electrode pad 14 moves while bypassing the non-conductive portion 16. Therefore, even in a case where the conductive film 13 is formed of the film of the transparent conductive oxide or the metal and the non-conductive portion 16 is formed by cutting the film of the transparent conductive oxide or the metal, the local deterioration can be suppressed while simultaneously achieving the heat generation function and the function of allowing the transmission of the electromagnetic wave in the specific frequency band.

In addition, in the above description, the size of the base unit U1 in the non-conductive portion 16 is designed corresponding to the frequency band of the electromagnetic wave to be transmitted through the non-conductive portion 16. For example, in order to allow transmission of an electromagnetic wave in a millimeter wave frequency band centering on 76.5 GHz, the width of the base unit U1 in the direction in which the base unit U1 extends, that is, the width L1 can be designed to 665 μm. In the present invention, for example, the length L1 can be designed to be 0.1 mm or more, that is, 100 μm or more and 1000.0 mm or less.

In addition, in the above description, the non-conductive portion 16 is configured by four base units U1. The non-conductive portion 16 can also be configured by two base units, can also be configured by three base units, or can also be configured by five or more base units.

For example, FIG. 6 shows an example of a non-conductive portion 36 configured by three base units U3. The non-conductive portion 36 is configured by the three base units U3 having a rectangular shape being connected to each other at a connection point C3, and is surrounded by an edge portion 38 formed of the conductive wirings 15. In addition, the three base units U3 extend from the connection point C3 in different directions.

In addition, in the above description, the base unit U1 of the non-conductive portion 16 has a rectangular shape. The shape of the base unit U1 is not particularly limited as long as it is an elongated shape.

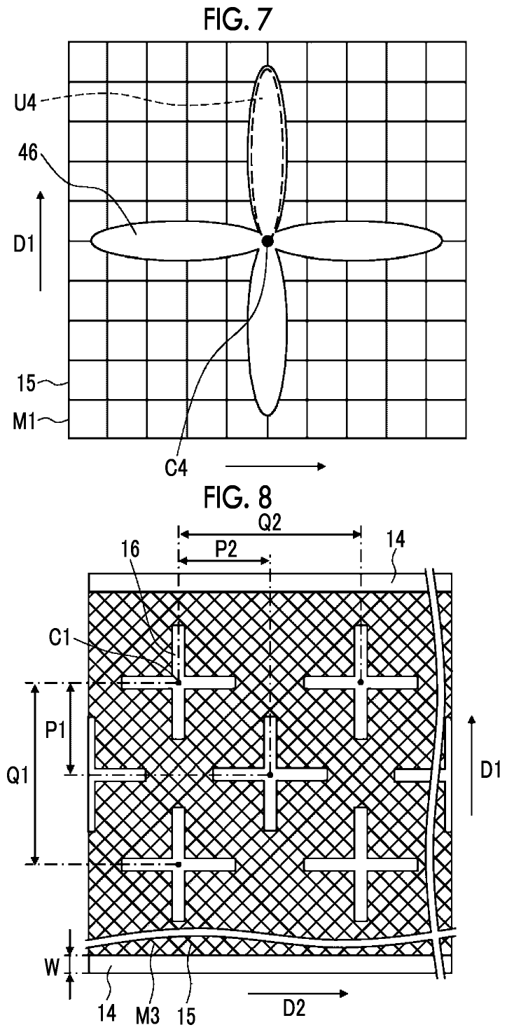

For example, FIG. 7 shows an example of a non-conductive portion 46 including base units U4 having an elongated elliptical shape. The non-conductive portion 46 is configured by the four base units U4 having an elliptical shape being connected to each other to form a cross shape at a connection point C4. The four base units U4 extend in different directions including the first direction D1, a direction opposite to the first direction D1, the second direction D2, and a direction opposite to the second direction D2.

In addition, the four base units U1 of the non-conductive portion 16 extend in the same directions as directions in which the plurality of conductive wirings 15 extend. For example, as shown in FIG. 8, the directions in which the four base units U1 extend may be different from the directions in which the plurality of conductive wirings 15 extend. In the example of FIG. 8, the plurality of conductive wirings 15 extend in the directions intersecting with the first direction D1 and the second direction D2. As a result, a conductive mesh M3 is formed. Even in this case, with the conductive member 11, the local deterioration can be suppressed while simultaneously achieving the heat generation function and the function of allowing the transmission of the electromagnetic wave in the specific frequency band.

However, in a case where the directions in which the four base units U1 extend and the directions in which the plurality of conductive wirings 15 extend are the same, the presence of the cross-shaped non-conductive portion 16 is inconspicuous during observation of the conductive member 11. Therefore, for example, in a case where transparency is required for the conductive member 11, from the viewpoint of making the presence of the non-conductive portion 16 inconspicuous, it is preferable that the directions in which the four base units U1 extend and the directions in which the plurality of conductive wirings 15 extend are the same.

### Second Embodiment

In the non-conductive portion 16 according to the first embodiment, the conductive wiring 15 is not disposed. However, the conductive wiring 15 that is not electrically connected to the pair of electrode pads 14 can be disposed in the non-conductive portion 16.

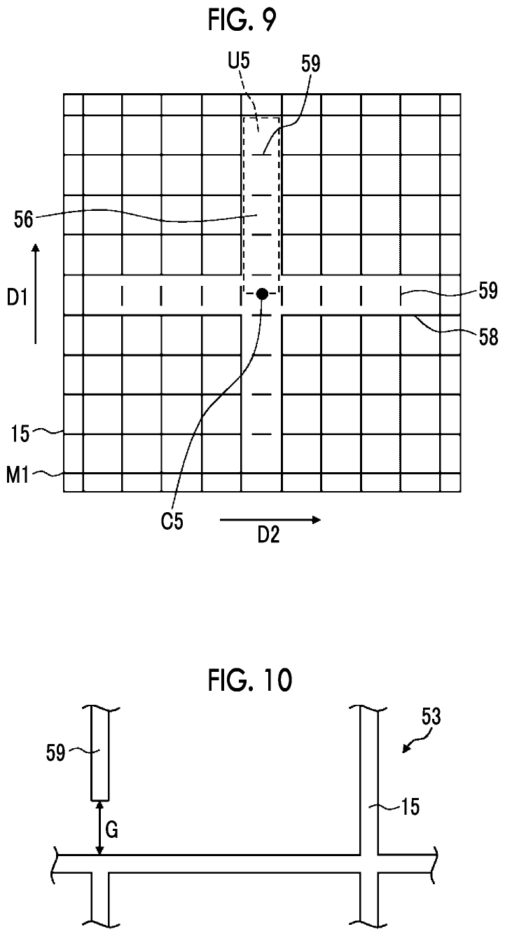

FIG. 9 shows a non-conductive portion 56 according to a second embodiment. As in the non-conductive portion 16 according to the first embodiment, the non-conductive portion 56 is surrounded by a cross-shaped edge portion 58 formed of the conductive wirings 15, in which base units U5 having a rectangular shape are connected in a cross shape at a connection point C5. The non-conductive portion 16 may include a plurality of dummy wirings 59. The dummy wirings 59 is formed of the same material as the conductive wiring 15, and is disposed to overlap in parallel an extension line of the conductive wiring 15 electrically connected to the pair of electrode pads 14.

In addition, as shown in FIG. 10, the dummy wiring 59 is disposed at a gap G from the conductive wiring 15 electrically connected to the pair of electrode pads 14. Therefore, the dummy wiring 59 is electrically insulated from the pair of electrode pads 14.

In addition, in order to make the presence of the gap G inconspicuous, it is preferable that the gap G is designed to have a length in a range of 0.01 μm to 2.00 μm.

This way, by disposing the plurality of dummy wirings 59 in the non-conductive portion 56, in a case where the conductive member according to the second embodiment is observed by an observer, the presence of the non-conductive portion 56 can be made inconspicuous. Therefore, for example, in a case where the conductive member according to the second embodiment covers a member of which the design is desired to be visible to an external observer, for example, an emblem of automobile, deterioration in the design of the member can be prevented, which is particularly useful.

### Third Embodiment

In the conductive member 11 according to the first embodiment, in the conductive film 13, the non-conductive portion 16 is disposed on any path A1 that linearly connects the pair of electrode pads 14 to each other in the first direction D1. However, as long as the plurality of non-conductive portions 16 are arranged such that the direction in which the line segment F1 that connects the connection points C1 of two non-conductive portions 16 closest to each other among the plurality of non-conductive portions 16 extends is different from each of the directions in which the four base units U1 extend, the path A1 that linearly connects the pair of electrode pads 14 and the passes through a gap between the non-conductive portions 16 may be present.

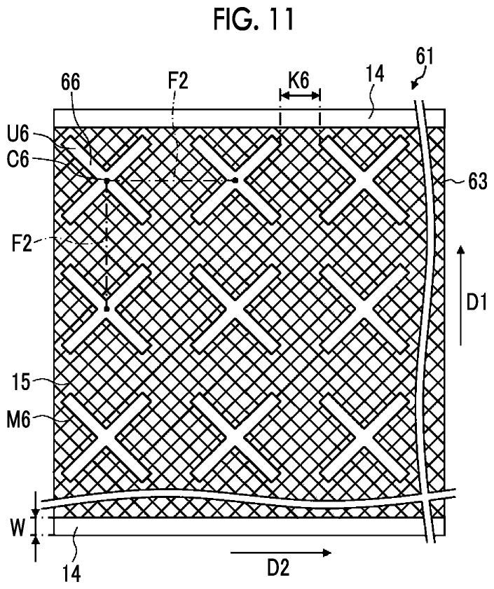

FIG. 11 shows a conductive member 61 according to a third embodiment. The conductive member 61 includes non-conductive portions 66 formed by rotating the non-conductive portions 16 by 45° instead of the non-conductive portions 16 in the conductive member 11 according to the first embodiment, and may further include a conductive mesh M6 formed by rotating the plurality of conductive wirings 15 by 45° instead of the conductive mesh M1.

Two non-conductive portions 66 closest to each other among the plurality of non-conductive portions 66 are lined up in the first direction D1 or the second direction D2, and four base units U6 of the non-conductive portion 66 extend from a connection point C6 in directions intersecting the first direction D1 and the second direction D2. Therefore, the plurality of non-conductive portions 66 are arranged such that a direction in which a line segment F2 that connects the connection points C6 of two non-conductive portions 66 closest to each other among the plurality of non-conductive portions 66 extends is different from each of the directions in which the four base units U6 extend.

In a conductive film 63, a path that linearly connects the pair of electrode pads 14 in the first direction D1 is present between two non-conductive portions 66 closest to each other, but the direction in which the line segment F2 that connects the connection points C6 of two non-conductive portions 66 closest to each other among the plurality of non-conductive portions 66 extends is different from each of the directions in which the four base units U6 extend. Therefore, a distance K6 between the two non-conductive portions 66 can be designed to be wide such that a current does not significantly concentrate. Therefore, a local increase in the density of a current flowing between the pair of electrode pads 14 can be alleviated, and deterioration of the conductive mesh M6 can be suppressed.

As described above, in the conductive member 61 according to the third embodiment, the plurality of non-conductive portions 66 are arranged such that the direction in which the line segment F2 that connects the connection points C6 of two non-conductive portions 66 closest to each other among the plurality of non-conductive portions 66 extends is different from the directions in which the four base units U6 each of the non-conductive portions 66 extend. Therefore, the local deterioration can be suppressed while simultaneously achieving the heat generation function and the function of allowing the transmission of the electromagnetic wave in the specific frequency band.

Hereinafter, each of the members forming the conductive member 11 according to the first embodiment will be described in detail. The following description is also applicable to each of the members of the conductive member according to the second embodiment and the conductive member 61 according to the third embodiment.

<Substrate>

The substrate 12 is not particularly limited as long as it has insulating properties and can support at least the conductive film 13. However, it is preferable that the substrate 12 is transparent and is formed of a resin material.

Specific examples of the resin material forming the substrate 12 include polymethyl methacrylate (PMMA), acrylonitrile butadiene styrene (ABS), polyethylene terephthalate (PET), polycarbonate (PC), polycycloolefin, (meth)acryl, polyethylene naphthalate (PEN), polyethylene (PE), polypropylene (PP), polystyrene (PS), polyvinyl chloride (PVC), polyvinylidene chloride (PVDC), polyvinylidene difluoride (PVDF), polyarylate (PAR), polyethersulfone (PES), polymer acryl, a fluorene derivative, a crystalline cycloolefin polymer (COP), and triacetyl cellulose (TAC).

Here, from the viewpoints of the transparency and the durability of the substrate 12, it is preferable that the substrate 12 includes, as a major component, any one of a polymethyl methacrylate resin, a polycarbonate resin, an acrylonitrile/butadiene/styrene resin, or a polyethylene terephthalate resin. Here, the major component of the substrate 12 refers to a component of which the content is 80% or more with respect to the components of the substrate 12.

The visible light transmittance of the substrate 12 is preferably 85.0% to 100.0%.

In addition, the thickness of the substrate 12 is not particularly limited, and from the viewpoint of handleability or the like, is preferably 0.05 mm or more and 2.00 mm or less and more preferably 0.10 mm or more and 1.00 mm or less.

<Primer Layer>

In order to strongly support a conductive layer 13, a primer layer may be provided between the substrate 12 and the conductive layer 13. The material of the primer layer is not limited as long as the conductive layer 13 can be strongly supported. In a case where the conductive film 13 is formed of the plurality of conductive wirings 15, it is particularly preferable that the primer layer is formed of a urethane-based resin material.

<Conductive Wiring>

The conductive wiring 15 is formed of a conductive material. As the conductive wiring 15, a metal, a metal oxide, a carbon material, a conductive polymer, or the like can be used. For example, in a case where the conductive wiring 15 is formed of a metal, the kind of the metal is not particularly limited, and examples thereof include copper, silver, aluminum, chromium, lead, nickel, gold, tin, and zinc. From the viewpoint of conductivity, copper, silver, aluminum, or gold is preferable. Examples of a method forming the metallic conductive wiring include a semi-additive method a fully additive method, a subtractive method, a silver halide method, printing of a metal-containing ink or a precursor thereof, an ink jet method, or a laser direct structuring method can be used, and a combination of the above methods can also be used. As the metal, a bulk material can be used, and nanowires or nanoparticles can also be used. In a case where the conductive wiring 15 is formed of a carbon material, the structure or the composition thereof as the conductive wiring 15 is not particularly limited, and carbon nanotubes, fullerene, carbon nanobuds, graphene, graphite, or the like can be used. In a case where the conductive wiring 15 is formed of a metal oxide, an indium tin oxide (ITO) can be used as the conductive wiring 15. In a case where the conductive wiring 15 is formed of a conductive polymer, for example, poly(3,4-ethylenedioxythiophene) polystyrene sulfonate (PEDOT-PSS) can be used as the conductive wiring 15.

### EXAMPLES

The present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

### Example 1

(Preparation of Substrate)

A polycarbonate resin film (PANLITE PC-2151, manufactured by Teijin Ltd.) having a thickness of 250.0 μm was prepared as a substrate.

(Preparation of Composition for Forming Primer Layer)

The following components were mixed to obtain a composition for forming a primer layer.

| | |
|---|---|
| Z913-3 (manufactured by Aica Kogyo Co.. Ltd.) | 33 parts by mass |
| IPA (isopropyl alcohol) | 67 parts by mass |

(Formation of Primer Layer)

The obtained composition for forming a primer layer was applied using a bar coating method to the substrate such that an average dry film thickness was 1.0 μm, and was dried at 80° C. for 3 minutes. Next, the formed layer of the composition for forming a primer layer was irradiated with ultraviolet (UV) rays at an irradiation dose of 1000 mJ to form a primer layer having a thickness of 0.8 μm.

(Preparation of Composition for Forming Plated Layer Precursor Layer)

The following components were mixed to obtain a composition for forming a plated layer precursor layer.

| | |
|---|---|
| IPA (isopropyl alcohol | 38.00 parts by mass |
| Polybutadiene maleic acid | 4.00 parts by mass |
| FOM-03008 (manufactured by Fujifilm Wako | 1.00 part by mass |
| Pure Chemical Corporation) | |
| IRGACURE OXE02 (manufactured by BASF SE, | 0.05 parts by mass |
| ClogP = 6.55) | |

FOM-03008 includes a compound represented by the following formula as a major component.

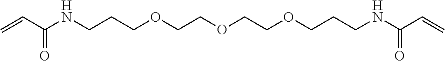 [SMILES: C=CC(=O)NCCCOCCOCCOCCCNC(=O)C=C]

(Preparation of Substrate with Plated Layer Precursor Layer)

The obtained composition for forming a plated layer precursor layer was applied using a bar coating method to the primer layer such that the film thickness was 0.2 μm, and was dried in an atmosphere of 120° C. for 1 minute. Next, by bonding a polypropylene film having a thickness of 12.0 μm to the composition for forming a plated layer precursor layer, a substrate with the plated layer precursor layer was prepared.

(Preparation of Substrate with Plated Layer)

A photo mask formed of quartz glass having a width of 110.804 mm in the first direction D1, having a width of 100.804 mm in the second direction D2, and having a thickness of 6.00 mm where patterns for exposure corresponding to the conductive mesh M1, the pair of electrode pads 14, and the plurality of non-conductive portions 16 shown in FIG. 2 were formed was prepared. In this photo mask, exposure patterns corresponding to the plurality of non-conductive portions 16 were arranged the direction in which the line segment F1 that connected the connection points C1 of two non-conductive portions 16 closest to each other among the plurality of non-conductive portions 16 extended was different from each of the directions in which the four base units U1 of each of the non-conductive portions 16 extended.

The line width of the pattern for exposure corresponding to the conductive wiring 15 was 4 μm, and the interval of the exposure patterns corresponding to conductive wirings 15 adjacent to each other was 150 μm. The width of the exposure pattern corresponding to the width L2 of the base unit U1 was 120 μm, and the width of the exposure pattern corresponding to the width L3 of the non-conductive portion 16 was 1330 μm. In the exposure pattern, the distance corresponding to the distance between the connection points C1 of two non-conductive portions 16 adjacent to each other in the first direction D1 or the second direction D2, that is, the pitch Q1 and the pitch Q2 was 2100 μm.

In addition, in the photo mask, the exposure patterns were formed such that 48 square regions where one non-conductive portion 16 in the center portion was surrounded by four connection points C1 as vertices were lined up in each of the first direction D1 and the second direction D2. Therefore, in the photo mask, the exposure patterns corresponding to 48²+(48−1)²=4513 non-conductive portions 16 were formed.

The substrate with the plated layer precursor layer was irradiated with ultraviolet light (energy amount: 200 mJ/cm², wavelength: 365 μm) through the photo mask. Next, the substrate with the plated layer precursor layer irradiated with ultraviolet light was developed by pure showering for 5 minutes. As a result, the substrate with the plated layer was prepared.

(Formation of Conductive Film)

The substrate with the plated layer was dipped in a 1 mass % sodium bicarbonate aqueous solution at 35° C. for 5 minutes. Next, the substrate with the plated layer was dipped in a palladium catalyst-added solution RONAMERSE SMT (manufactured by Rohm and Haas Electronic Materials LLC) at 55° C. for 5 minutes. The substrate with the plated layer was cleaned with water, was dipped in CIRCUPOSIT 6540 (manufactured by Rohm and Haas Electronic Materials LLC) at 35° C. for 5 minutes, and subsequently was cleaned with water again. Further, the substrate with the plated layer was dipped in CIRCUPOSIT 4500 (manufactured by Rohm and Haas Electronic Materials LLC) at 45° C. for 20 minutes and was cleaned with water to form a conductive film on the plated layer. As a result, a conductive member according to Example 1 where the conductive film formed of copper including the pair of electrode pads 14, the plurality of conductive wirings 15, and the plurality of non-conductive portions 16 shown in FIG. 2 was formed on the substrate was obtained.

In the conductive member according to Example 1, the distance between two non-conductive portions closest to each other was 504 μm, and the distance between the connection points of the two non-conductive portions was 1485 μm. Therefore, the distance between two non-conductive portions closest to each other was about 34% with respect to the distance between the connection points of the two non-conductive portions.

### Example 2

A conductive member according to Example 2 was prepared using the same method as that of Example 1, except that, as the photo mask used in the step of preparing the substrate with the plated layer according to Example 1, a photo mask where exposure patterns corresponding to the non-conductive portions 56 including the plurality of dummy wirings 59 shown in FIG. 9 were formed was used instead of using the photo mask where the exposure patterns corresponding to the non-conductive portions 16 shown in FIG. 4 were formed.

In the photo mask, the line width of the pattern for exposure corresponding to the conductive wiring 15 was 4 μm, and the interval of the exposure patterns corresponding to conductive wirings 15 adjacent to each other was 150 μm. The width of the exposure pattern corresponding to the width L2 of the base unit U5 was 150 μm, and the width of the exposure pattern corresponding to the width L3 of the non-conductive portion 56 was 1350 μm. In the exposure pattern, the distance corresponding to the distance between the connection points C5 of two non-conductive portions 56 adjacent to each other in the first direction D1 or the second direction D2 was 2100 μm.

In the conductive member according to Example 2, the distance between two non-conductive portions closest to each other was 424 μm, and the distance between the connection points of the two non-conductive portions was 1485 μm. Therefore, the distance between two non-conductive portions closest to each other was about 29% with respect to the distance between the connection points of the two non-conductive portions.

### Example 3

A conductive member according to Example 3 was prepared using the same method as that of Example 1, except that as the photo mask used in the step of preparing the substrate with the plated layer according to Example 1, a photo mask where the exposure patterns shown in FIG. 11 formed by rotating the plurality of conductive wirings 15 and the plurality of non-conductive portions 16 by 45° was used instead of using the photo mask where the exposure patterns corresponding to the plurality of conductive wirings 15 extending in the first direction D1 and the second direction D2 and the non-conductive portions 16 shown in FIG. 2 were formed. In the conductive member according to Example 3, as shown in FIG. 11, the direction in which the line segment F2 that connected the connection points C6 of two non-conductive portions 66 closest to each other among the plurality of non-conductive portions 66 extended was different from each of the directions in which the plurality of base units U6 extended. However, there was a portion where the non-conductive portion 66 was not disposed on the path that linearly connected the pair of electrode pads 14 to each other along the surface of the conductive film 13.

### Example 4

Using a silver halide method consisting of a step of preparing a silver halide emulsion, a step of preparing a composition for forming a photosensitive layer, a step of forming a photosensitive layer, a step of an exposure treatment and a development treatment, a step of a heating treatment, a step of a gelatin decomposition treatment, and a step of a polymer crosslinking treatment described below, a conductive member according to Example 4 where the conductive film formed of silver including the pair of electrode pads 14, the plurality of conductive wirings 15, and the plurality of non-conductive portions 16 shown in FIG. 2 was formed was obtained.

(Preparation of Silver Halide Emulsion)

The following solution 2 and the following solution 3 were simultaneously added for 20 minutes to the following solution 1 held at pH 4.5 and 38° C. in amounts corresponding to 90% of the entire amounts while stirring the solutions. As a result, nuclear particles having a size of 0.16 μm were formed. Next, the following solution 4 and the following solution 5 were added for 8 minutes, and the remaining 10% amounts of the solution 2 and the solution 3 were further added for 2 minutes. As a result, the nuclear particles grew to a size of 0.21 μm. Further, 0.15 g of potassium iodide was added, and the particles were aged for 5 minutes. Then the formation of the particles was completed.

Solution 1:

| | | |
|---|---|---|
| Water | 750 | ml |
| Gelatin | 8.6 | g |
| Sodium chloride | 3 | g |
| 1,3-Dimethylimidazolidine-2-thione | 20 | mg |
| Sodium benzenethiolsulfonate | 10 | mg |
| Citric acid | 0.7 | g |

Solution 2:

| | | |
|---|---|---|
| Water | 300 | ml |
| Silver nitrate | 150 | g |

Solution 3:

| | | |
|---|---|---|
| Water | 300 | ml |
| Sodium chloride | 38 | g |
| Potassium bromide | 32 | g |
| Potassium hexachloroiridate (III) | 5 | ml |
| (0.005% KCl 20% aqueous solution) | | |
| Ammonium hexachlororhodate | 7 | ml |

(0.001% NaCl 20% aqueous solution)

Solution 4:

| | | |
|---|---|---|
| Water | 100 | ml |
| Silver nitrate | 50 | g |

Solution 5:

| | | |
|---|---|---|
| Water | 100 | ml |
| Sodium chloride | 13 | g |
| Potassium bromide | 11 | g |
| Yellow prussiate of potash | 5 | mg |

Next, the particles were cleaned with water by flocculation using an ordinary method. Specifically, the temperature was decreased to 35° C., and the pH was decreased (to be in a range of pH 3.6±0.2) using sulfuric acid until silver halide precipitated. Next, about 3 L of the supernatant solution was removed (first water cleaning). Further, 3 L of distilled water was added, and sulfuric acid was added until silver halide precipitated. Next, about 3 L of the supernatant solution was removed again (second water cleaning). By repeating the same operation as the second water cleaning once more (third water cleaning), the water cleaning and desalting step was completed. After the water cleaning and desalting, the emulsion was adjusted to pH 6.4 and pAg 7.5, 2.5 g of gelatin, 10 mg of sodium benzenethiolsulfonate, 3 mg of sodium benzenethiosulfinate, 15 mg of sodium thiosulfate, and 10 mg of chloroauric acid were added, and chemosensitization was performed at 55° C. to obtain the optimum sensitivity. Next, 100 mg of 1,3,3a,7-tetraazaindene as a stabilizer and 100 mg of PROXEL (trade name, manufactured by ICI Co., Ltd.) as a preservative were added. The finally obtained emulsion was a silver iodochlorobromide cubic particle emulsion having an average particle diameter of 0.22 μm and a coefficient of variation of 9%, in which the content of silver iodide was 0.08 mol %, and the ratio of silver chlorobromide was 70 mol % of silver chloride/30 mol % of silver bromide.

(Preparation of Composition for Forming Photosensitive Layer)

1.2×10⁻⁴ mol/mol Ag of 1,3,3a,7-tetraazaindene, 1.2×10⁻² mol/mol Ag of hydroquinone, 3.0×10⁻⁴ mol/mol Ag of citric acid, 0.90 g/mol Ag of 2,4-dichloro-6-hydroxy-1,3,5-triazine sodium salt, and a small amount of a hardening agent were added to the emulsion, and the pH of the coating solution was adjusted to 5.6 using citric acid.

A polymer latex including a polymer represented by (P-1) shown below as an example and a dispersant formed of dialkylphenyl PEO sulfuric acid ester (a mass ratio dispersant/polymer was 2.0/100=0.02) was added to the coating solution such that a mass ratio polymer/gelatin of the polymer to the gelatin in the coating solution was 0.5/1.

Further, EPOXY RESIN DY022 (trade name, manufactured by Nagase ChemteX Corporation) as a crosslinking agent was added. The addition amount of the crosslinking agent was adjusted such that the amount of the crosslinking agent in the silver halide-containing photosensitive layer described below was 0.09 g/m².

This way, the composition for forming a photosensitive layer was prepared.

The polymer represented by (P-1) shown below as an example was synthesized with reference to JP3305459B and JP3754745B.

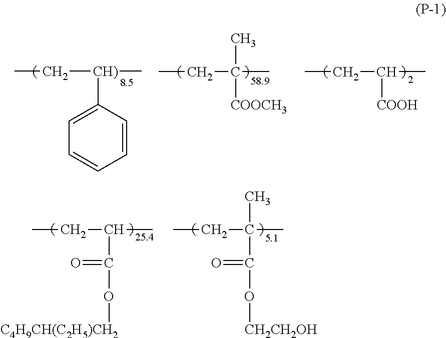

(Formation of Photosensitive Layer)

The above-described polymer latex was applied to the insulating substrate according to Example 1 to provide an undercoat layer having a thickness of 0.05 μm.

Next, a composition for forming a silver halide non-containing layer in which the polymer latex and gelatin were mixed with each other was applied to the undercoat layer to provide a silver halide non-containing layer having a thickness of 1.0 The mixing mass ratio (polymer/gelatin) of the polymer to the gelatin was 2/1, and the content of the polymer was 0.65 g/m².

Next, the composition for forming a photosensitive layer was applied to the silver halide non-containing layer to provide a silver halide-containing photosensitive layer having a thickness of 2.5 μm. The mixing mass ratio (polymer/gelatin) of the polymer to the gelatin in the silver halide-containing photosensitive layer was 0.5/1, and the content of the polymer was 0.22 g/m².

Next, a composition for forming a protective layer in which the polymer latex and gelatin were mixed with each other was applied to the silver halide-containing photosensitive layer to provide a protective layer having a thickness of 0.15 μm. The mixing mass ratio (polymer/gelatin) of the polymer to the gelatin was 0.1/1, and the content of the polymer was 0.015 g/m².

(Exposure Treatment and Development Treatment)

The photosensitive layer formed on the insulating substrate was exposed to light through the photo mask according to Example 1 using parallel light with a high pressure mercury lamp as a light source. After the exposure, the surface of the film was developed using the following developer, was developed using a fixing solution (trade name; N3X-R for CN16X, manufactured by Fujifilm Corporation), was rinsed with pure water, and then was dried.

Composition of Developer:
1 L of the developer included the following compounds.
Hydroquinone: 0.037 mol/L
N-methylamino phenol: 0.016 mol/L
Sodium metaborate: 0.140 mol/L
Sodium hydroxide: 0.360 mol/L
Sodium bromide: 0.031 mol/L
Potassium metabisulfite: 0.187 mol/L

(Heating Treatment)

Further, the dried insulating substrate was left to stand in a superheated steam bath at 120° C. for 130 seconds to heat the film.

(Gelatin Decomposition Treatment)

Further, the insulating substrate on which the heating treatment was performed was dipped in a gelatin decomposition solution (40° C.) prepared as described above for 120 seconds, was dipped in warm water (liquid temperature: 50° C.) for 120 seconds, and was cleaned. In the gelatin decomposition solution, triethanolamine and sulfuric acid were added to an aqueous solution (concentration of protease: 0.5 mass %) of protease (BIOPRASE 30 L, manufactured by Nagase ChemteX Corporation) to adjust the pH to 8.5.

(Polymer Crosslinking Treatment)

Further, the film was dipped in a CARBODILITE V-02-L2 (trade name: manufactured by Nisshinbo Chemical Inc.) 1% aqueous solution for 30 seconds, was extracted from the aqueous solution, was dipped in pure water (room temperature) for 60 seconds, and was cleaned. As a result, the conductive member according to Example 4 was obtained.

### Example 5

Using a silver nanowire method consisting of a step of preparing a silver nanowire dispersion liquid, a step of preparing a solution for adhesion, a step of preparing a non-patterned silver nanowire conductive substrate, and a step of preparing a patterned silver nanowire conductive substrate described below, a conductive member according to Example 5 where the conductive film formed of silver including the pair of electrode pads 14, the plurality of conductive wirings 15, and the plurality of non-conductive portions 16 shown in FIG. 2 was formed was obtained. The line width of the conductive wiring 15 was 30 μm.

(Preparation of Silver Nanowire Dispersion Liquid)

The following additive solutions A, B, C, and D were prepared.

<Additive Solution A>

60 mg of stearyltrimethylammonium chloride, 6.0 g of a stearylltrimethylammonium hydroxide 10% aqueous solution, and 2.0 g of glucose were dissolved in 120.0 g of distilled water to prepare a reaction solution A-1. Separately, 72 mg of silver nitrate powder was dissolved in 2.0 g of distilled water to prepare a silver nitrate aqueous solution A-2.

Further, the reaction solution A-1 was kept at 25° C., and the silver nitrate aqueous solution A-2 was added to the reaction solution A-1 while strongly stifling the reaction solution A-1. After adding the silver nitrate aqueous solution A-2, the reaction solution A-1 was strongly stirred for 180 minutes to obtain an additive solution A.

<Additive Solution B>

42.0 g of silver nitrate powder was dissolved in 958 g of distilled water to obtain an additive solution B.

<Additive Solution C>

75 g of 25% ammonia water was mixed with 925 g of distilled water to obtain an additive solution C.

<Additive Solution D>

400 g polyvinylpyrrolidone (K30) was dissolved in 1.6 kg of distilled water to obtain an additive solution D.

Next, a silver nanowire dispersion liquid was prepared as follows.

First, 1.30 g of stearyltrimethylammonium bromide powder, 33.1 g of sodium bromide powder, 1000 g of glucose powder, and 115.0 g of nitric acid (1N) were dissolved in 12.7 kg of distilled water at 80° C. This solution was kept at 80° C., and the additive solution A was added at an addition rate of 250 cc/min, the additive solution B was added at an addition rate of 500 cc/min, and the additive solution C was added at an addition rate of 500 cc/min sequentially while stirring the solution at 500 rpm. The solution to which the additive solution A, the additive solution B, and the additive solution C were added was heated and stirred at a stirring rate of 200 rpm for 100 minutes while keeping the liquid temperature at 80° C. Next, this solution was cooled to 25° C. After changing the stirring rate to 500 rpm, the additive solution D was added to the solution at 500 cc/min. This way, the solution to which the additive solution D was added was obtained as a preliminary liquid E1.

Next, while strongly stirring 1-propanol, the preliminary liquid E1 was instantaneously added thereto such that a mixing ratio between 1-propanol and the preliminary liquid E1 was 1:1 by volume ratio. This way, the solution to which 1-propanol was added to the preliminary liquid E1 was stirred for 3 minutes to obtain a preliminary liquid E2.

Further, using an ultrafiltration module having a molecular weight cutoff of 150000, ultrafiltration was performed on the preliminary liquid E2 as follows. After concentrating the obtained preliminary liquid E2 to 4 times, addition and concentration of a mixed solution (volume ratio=1:1) between distilled water and 1-propanol on the preliminary liquid E2 concentrated to 4 times were repeated until the conductivity of the filtrate finally reached 50 μS/cm or less. As a result, a silver nanowire dispersion liquid having a metal content of 0.45% was obtained.

(Preparation of Solution for Adhesion)

According to the following formulation, a solution for adhesion was prepared.

<Solution for Adhesion>

| | |
|---|---|
| Tetraethoxysilane (KBE-04, manufactured by Shin-Etsu Chemical Co., Ltd.) | 5.0 parts by mass |
| 3-glycidyloxypropyltrimethoxysilane | 3.2 parts by mass |
| (KBM-403, manufactured by Shin-Etsu Chemical Co., Ltd.) | |
| 2-(3,4-epoxycyclohexyl)ethyltrimethoxysilane | 1.8 parts by mass |
| (KBM-303, manufactured by Shin-Etsu Chemical Co., Ltd.) | |
| Acetic acid aqueous solution (acetic acid concentration = 0.05%, pH = 5.2) | 10.0 parts by mass |
| Curing agent (boric acid, manufactured by Wako Pure Chemical Industries, Ltd.) | 0.8 parts by mass |
| Colloidal silica | 60.0 parts by mass |
| (SNOWTEX O, average particle diameter: 10 nm to 20 nm, concentration of solid | |
| contents: 20%, pH = 2.6, manufactured by Nissan Chemical Industries Ltd.) | |
| Surfactant | 0.2 parts by mass |
| (NAROACTY HN-100, manufactured by Sanyo Chemical Industries Ltd.) | |

The solution for adhesion was prepared using the following method.

First, while strongly stirring the acetic acid aqueous solution, 3-glycidyloxypropyltrimethoxysilane was added dropwise for 3 minutes to obtain an aqueous solution 1. Next, while strongly stirring the aqueous solution 1, 2-(3,4-epoxycyclohexyl)ethyltrimethoxysilane was added for 3 minutes to obtain an aqueous solution 2. Next, while strongly stirring the aqueous solution 2, tetraethoxysilane was added for 5 minutes and was continuously stirred for 2 hours to obtain an aqueous solution 3. Next, colloidal silica, the curing agent, and the surfactant were sequentially added to the aqueous solution 3 to prepare the solution for adhesion.

(Preparation of Non-Patterned Silver Nanowire Conductive Substrate)

After performing a corona discharge treatment on a surface of a polycarbonate substrate (polycarbonate resin film (PANLITE PC-2151, manufactured by Teijin Ltd.), thickness: 250 μm), a 0.02% N-β-(aminoethyl)-γ-aminopropyltrimethoxysilane aqueous solution was applied using a bar coating method such that the application amount was 8.8 mg/m², and was dried at 100° C. for 1 minute to obtain the surface-treated polycarbonate substrate.

Further, after performing a corona discharge treatment on the treated surface of the polycarbonate substrate, the solution for adhesion was applied to the surface using a bar coating method, and was heated and dried at 170° C. for 1 minute to form an adhesive layer having a thickness of 0.5 μm. As a result, the polycarbonate substrate with the adhesive layer was obtained.

After verifying that a solution of an alkoxide compound having the following composition was stirred at 60° for 1 hour to make the solution uniform, a sol-gel solution was obtained. 2.24 parts by mass of the obtained sol-gel solution and 17.76 parts by mass of the silver nanowire dispersion liquid obtained in the step of preparing the silver nanowire dispersion liquid were mixed, and the mixed solution was diluted with distilled water and 1-propanol to obtain a liquid composition (sol-gel coating liquid). A solvent ratio in the obtained liquid composition was distilled water:1-propanol=60:40.

<Solution of Alkoxide Compound>

| | |
|---|---|
| Tetraethoxysilane (KBE-04, manufactured by | 5.0 parts by mass |
| Shin-Etsu Chemical Co., Ltd.) | |
| 1% acetic acid aqueous solution | 11.0 parts by mass |
| Distilled water | 4.0 parts by mass |

A corona discharge treatment was performed on the surface of the adhesive layer of the polycarbonate substrate with the adhesive layer, and the liquid composition (sol-gel coating liquid) was applied to the surface using a bar coating method such the silver content was 0.015 g/m² and the total solid content application amount was 0.120 g/m², and was heated at 100° C. for 1 minute. As a result, a sol-gel reaction occurred, and a conductive layer was formed. This way, a non-patterned silver nanowire conductive substrate was obtained. A mass ratio between tetraethoxysilane (alkoxide compound) and silver nanowires in the conductive layer was 7:1.

(Preparation of Patterned Silver Nanowire Conductive Substrate)

A solution (etchant) was applied to the non-patterned silver nanowire conductive substrate obtained as described above using a screen printing method in a patterned manner for patterning.

For the screen printing, WHT-3 type and squeegee No. 4 yellow manufactured by Mino Group Co., Ltd. were used. The etchant of the silver nanowires for forming the pattern was prepared by mixing a CP-48S-A solution and a CP-48S-B solution (both of which are manufactured by Fujifilm Corporation) with pure water at 1:1:1 and thickening the mixed solution with hydroxyethyl cellulose, and was used as ink for the screen printing. As a pattern used for the screen printing, the same pattern as the exposure pattern of the photo mask used in Example 1 where the line width of a portion corresponding to the conductive wiring 15 was 30 μm was used. The etchant was applied to the non-patterned silver nanowire conductive substrate such that the application amount was 0.01 g/cm², was left to stand at 25° C. for 2 minutes, and was clean with pure water for patterning.

By performing the above-described patterning treatment, a patterned silver nanowire conductive substrate including a conductive layer having a conductive region and a non-conductive region was obtained. The patterned silver nanowire conductive substrate was the conductive member according to Example 5.

### Example 6

A conductive member according to Example 6 was prepared using the same method as that of Example 1, except for a step of forming a primer layer, a step of preparing a composition for forming a plated layer precursor layer, and a step of preparing a substrate with a plated layer precursor layer described below.

(Formation of Primer Layer)

First, the following components were mixed to obtain a composition for forming a primer layer.

| | |
|---|---|
| Copolymer A | 25.0 parts by mass |
| MFG (1-methoxy-2-propanol) | 74.8 parts by mass |
| Omnirad 184 (manufactured by IGM Resins B.V.) | 0.2 parts by mass |

Omnirad 184 includes a compound represented by the following formula as a major component.

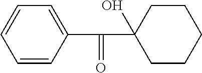 [SMILES: O=C(c1ccccc1)C1(O)CCCCC1]

Here, the copolymer A is copolymer in which the polyol component ratio was 2 times that commercially available 8UX-196A (manufactured by Taisei Fine Chemical Co., Ltd.) and the weight-average molecular weight was 40000.

The obtained composition for forming a primer layer was applied using a bar coating method to the substrate such that an average dry film thickness was 1.6 μm, and was dried at 100° C. for 10 minutes. Next, the formed layer of the composition for forming a primer layer was irradiated with ultraviolet (UV) rays at an irradiation dose of 500 mJ to form a primer layer having a thickness of 1.5 μm.

(Preparation of Composition for Forming Plated Layer Precursor Layer)

Next, a composition for forming a plated layer precursor layer was prepared. The following components were mixed to obtain a composition for forming a plated layer precursor layer.

| | |
|---|---|
| IPA (Isopropyl alcohol) | 38.00 parts by mass |
| Polybutadiene maleic acid | 4.00 parts by mass |
| FOM-03008 (manufactured by Fujifilm Wako | 1.00 part by mass |
| Pure Chemical Corporation) | |
| IRGACURE OXE02 (manufactured by BASF SE, | 0.10 parts by mass |
| ClogP = 6.55) | |

FOM-03008 includes a compound represented by the following formula as a major component.

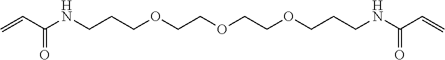 [SMILES: C=CC(=O)NCCCOCCOCCOCCCNC(=O)C=C]

(Step of Preparing Substrate with Plated Layer Precursor Layer)

The obtained composition for forming a plated layer precursor layer was applied using a bar coating method to the primer layer such that the film thickness was 0.4 μm, and was dried in an atmosphere of 120° C. for 1 minute. Next, by bonding a polypropylene film having a thickness of 12.0 μm to the composition for forming a plated layer precursor layer, a substrate with the plated layer precursor layer was prepared.

The subsequent steps were performed using the same method as in Example 1 to prepare a conductive member according to Example 6.

### Comparative Example 1

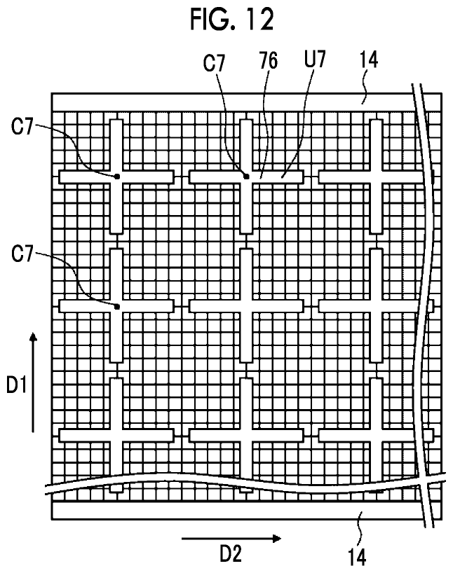

A conductive member according to Comparative Example 1 was prepared using the same method as that of Example 1, except that, as the photo mask used in the step of preparing the substrate with the plated layer according to Example 1, a photo mask where exposure patterns including a plurality of non-conductive portions 76 arranged in a square grid shape at a given interval in the first direction D1 and the second direction D2 were formed for example, as shown in FIG. 12 in “Vyachesla V. Komarov, Valery P. Meschanov, “Transmission properties of metal mesh filters at 90 GHz”, Journal of Computational Electronics, Feb. 28, 2019, 18:696-704 was used instead of using the photo mask where the exposure patterns corresponding to the plurality of non-conductive portions 16 shown in FIG. 2 were formed.

In the photo mask used in Comparative Example 1, two non-conductive portions 76 arranged adjacent to each other in the first direction D1 and two non-conductive portions 76 arranged adjacent to each other in the second direction D2 are two non-conductive portions 76 closest to each other among the plurality of non-conductive portions 76. In addition, in the photo mask, the exposure patterns corresponding to the plurality of non-conductive portions 26 were arranged such that directions in which a line segment that connected connection points C7 of two non-conductive portions 76 closest to each other extended, that is, the first direction D1 and the second direction D2 were the same as directions in which four base units U7 of the non-conductive portion 26 extended.

In the photo mask, the line width of the pattern for exposure corresponding to the conductive wiring 25 was 4 μm, and the interval of the exposure patterns corresponding to conductive wirings 25 adjacent to each other was 150 μm. The width of the exposure pattern corresponding to the width L2 of the base unit U2 was 120 μm, and the width of the exposure pattern corresponding to the width L3 of the non-conductive portion 56 was 1290 μm. In the exposure pattern, the distance corresponding to the distance between the connection points C2 of two non-conductive portions 56 adjacent to each other in the first direction D1 or the second direction D2, that is the pitch P3 was 1500 μm.

In addition, in the photo mask, the exposure patterns were formed such that 66 regions including one non-conductive portion 16 in the center portion and having a width of 1500 μm in the first direction D1 and the second direction D2 were lined up in each of the first direction D1 and the second direction D2. Therefore, in the photo mask, the exposure patterns corresponding to 66×66=4356 non-conductive portions 26 were formed.

### Comparative Example 2

A conductive member according to Comparative Example 2 was prepared using the same method as that of Example 1, except that, as the photo mask used in the step of preparing the substrate with the plated layer according to Example 1, a photo mask including only exposure patterns corresponding to the conductive mesh M1 and the pair of electrode pads 14 shown in FIG. 2 without including the exposure pattern corresponding to the non-conductive portion was used.

For the conductive members according to Examples 1 to 6 and Comparative Examples 1 and 2 obtained as described above, the following evaluations were performed.

(Deterioration Evaluation)

First, a conductive tape was bonded to the entire region of each of the pair of electrode pads of the conductive member to measure a resistance value R1 between the conductive tapes. Next, the conductive member was fixed such that the conductive film was orthogonal to a horizontal surface. In this case, any obstacle was not disposed in a range of 150 mm on opposite surfaces of the conductive film. Next, a crocodile clip connected to a power supply device (DME 1600 manufactured by Kikusui Electronics Corporation; a digital multimeter) was attached to each of the conductive tapes attached to the pair of electrode pads. By bonding two conductive tapes to the same electrode pad in advance such that the two conductive tapes did not come into contact with each other to measure resistances thereof, a contact resistance was measured through the electrode pad. It was verified that the contact resistance was 0.05Ω or less which was sufficiently ignorable with respect to the resistance value R1.

Next, the conductive member was disposed in a constant-temperature tank set to conditions of temperature: 25° C., relative humidity: 60%, and a windless environment, and a voltage was continuously applied to the conductive film using the power supply device for 2000 hours while keeping the temperature of the conductive film at 100° C. In this case, the temperature of the conductive film was measured using a thermometer (ETS320 manufactured by FLIR). 2000 hours after applying a voltage to the conductive film, a resistance value R2 between the conductive tapes attached to the pair of electrode pads was measured, and a deterioration factor R2/R1 was calculated based on a ratio of the resistance value R2 to the resistance value R1. The conductive member where the calculated deterioration factor R2/R1 was 1.2 or less was evaluated as A where deterioration was sufficiently suppressed, and the conductive member where the calculated deterioration factor R2/R1 was more than 1.2 was evaluated as B where deterioration occurred clearly.

(Millimeter Wave Transmission Evaluation)

The transmittance of the conductive member with respect to a millimeter wave in a specific wavelength was measured using millimeter wave network analyzer (N5290A, manufactured by Keysight Technologies Inc.). In this case, first the conductive member was bonded to a stainless steel plate having a thickness of 2 mm having a hole with a diameter of 80 mm. In addition, the millimeter wave network analyzer was disposed such that two ports faced each other. In addition, the conductive member bonded to the stainless steel plate was disposed such that the hole having a diameter of 80 mm of the stainless steel plate was positioned at an intermediate point between the two ports and the flat surface of the conductive member was perpendicular to a line segment connecting the two ports. In this state, the transmittance of the conductive member with respect to a millimeter wave in 76.5 GHz was measured. Assuming that the transmittance measured without disposing the conductive member between the two ports was 0 dB, the transmittance of the conductive member was calculated. A case where the measured transmittance was −1.0 dB or more was evaluated as A, and a case where the measured transmittance was less than −1.0 dB was evaluated as B.

(Temperature Uniformity Evaluation)

As in the deterioration test, a conductive tape was bonded to the entire region of each of the pair of electrode pads of the conductive member. In a state where the conductive member was fixed such that the conductive film was orthogonal to a horizontal surface, the conductive member was disposed in a constant-temperature tank set to conditions of temperature: 10° C., relative humidity: 60%, and a windless environment. In this state, a voltage was applied to the conductive film of the conductive member using a power supply device such that the temperature of the conductive film was 35° C. while measuring the temperature using a thermometer. Further, using the same thermometer, a temperature distribution in a range of 50 mm×50 mm of a center portion of the conductive film was measured. The conductive member where a temperature difference between a highest temperature and a lowest temperature among the measured temperatures was less than 3° C. was evaluated as A where the temperature distribution was uniform, and the conductive member where a temperature difference between a highest temperature and a lowest temperature among the measured temperatures was 3° C. or more was evaluated as B where the temperature distribution was not uniform.

(Visibility Evaluation)

10 observers were positioned at positions at a distance of 1 m from the conductive member, and in a state where the conductive member was irradiated with a fluorescent lamp, each of the observers visually inspected the conductive member to evaluate whether or not the non-conductive portion was visible. A case where less than 5 observers out of the 10 observers evaluated that the non-conductive portion was visible was evaluated as A for the conductive member, and a case where less 5 or more observers out of the 10 observers evaluated that the non-conductive portion was visible was evaluated as B for the conductive member.

Table 1 below shows the results of the deterioration evaluation and the millimeter wave transmission evaluation for Examples 1 to 6 and Comparative Examples 1 and 2.

TABLE 1

| | | Direction of Line Segment | | | | |
|---|---|---|---|---|---|---|
| | | Connecting Connection | | | | |
| | | Points of Non-Conductive | | | | Millimeter Wave |
| | Non-Conductive | Portions Closest to Each | Deterioration | Transmittance | Deterioration | Transmission |
| | Portion | Other | Factor R2/R1 | (dB) | Evaluation | Evaluation |
| Example 1 | Present | Different from Direction of | 1.0 | −0.7 | A | A |
| | | Base Unit | | | | |
| Example 2 | Present | Different from Direction of | 1.0 | −0.7 | A | A |
| | | Base Unit | | | | |
| Example 3 | Present | Different from Direction of | 1.0 | −0.7 | A | A |
| | | Base Unit | | | | |
| Example 4 | Present | Different from Direction of | 1.0 | −0.8 | A | A |
| | | Base Unit | | | | |
| Example 5 | Present | Different from Direction of | 1.0 | −0.9 | A | A |
| | | Base Unit | | | | |
| Example 6 | Present | Different from Direction of | 1.0 | −0.7 | A | A |
| | | Base Unit | | | | |
| Comparative | Present | Same as Direction of Base | 1.3 | −0.7 | B | A |
| Example 1 | | Unit | | | | |
| Comparative | Not Present | | 1.0 | −14.3 | A | B |
| Example 2 | | | | | | |

As shown in Table 1, it can be seen that, in the conductive members according to Examples 1 to 6, the results of the deterioration evaluation and the millimeter wave transmission evaluation were all A, and the function of allowing transmission of the millimeter wave was provided and the deterioration of the conductive wiring was not likely to occur even in a case where the conductive film was energized.

In the conductive members according to Examples 1 to 6, the plurality of non-conductive portions were formed such that the direction in which the line segment that connected the connection points of two non-conductive portions closest to each other among the plurality of non-conductive portions extended was different from each of the directions in which the plurality of base units of the non-conductive portion extended. Therefore, it is considered that the distance between the non-conductive portions is relatively wide, and a portion where the current density rapidly increases is not generated. Therefore, oxidation or the like of the conductive wiring caused by excessive heat generation is suppressed, and deterioration of the conductive wiring is also suppressed.

On the other hand, it can be seen that, in the conductive member according to Comparative Example 1, the result of the deterioration evaluation was B, and deterioration of the conductive wiring was likely to occur by energizing the conductive film.

In the conductive member according to Comparative Example 1, the plurality of non-conductive portions were formed such that the direction in which the line segment that connected the connection points of two non-conductive portions closest to each other among the plurality of non-conductive portions extended was the same as each of the directions in which the plurality of base units of the non-conductive portion extended. Therefore, it is considered that the distance between the non-conductive portions is relatively narrow, and a portion where the current density rapidly increases is generated. Therefore, excessive heat generation locally occurs such that the oxidation or the like of the conductive wiring is likely to occur and the conductive wiring is likely to deteriorate.

In addition, it can be seen that, in the conductive member according to Comparative Example 2, the result of the millimeter wave transmission evaluation was B, and the function of allowing transmission of the millimeter wave was not provided. The reason for this is presumed to be that the conductive member according to Comparative Example 2 does not include the non-conductive portion.

Next, Table 2 below shows the results of the temperature uniformity evaluation for Examples 1 to 6.

TABLE 2

| | Non-Conductive Portion being | Temperature |
|---|---|---|
| | Disposed on Any Path Linearly | Uniformity |
| | Connecting Pair of Electrode pads | Evaluation |
| Example 1 | ∘ | A |
| Example 2 | ∘ | A |
| Example 3 | x | B |
| Example 4 | ∘ | A |
| Example 5 | ∘ | A |
| Example 6 | ∘ | A |

In addition, in the conductive member according to Examples 1, 2, and 4 to 6, the result of the temperature uniformity evaluation was A. On the other hand, in the conductive member according to Example 3, the result of the temperature uniformity evaluation was B.

In the conductive members according to Examples 1, 2, and 4 to 6, in the conductive film, the non-conductive portion was disposed on any path that linearly connected the pair of electrode pads to each other in the first direction D1. Therefore, it is considered that a current flowing from one electrode pad to another electrode pad moves while uniformly bypassing the plurality of non-conductive portions. Therefore, it is considered that a local temperature increase is not likely to occur.

In the conductive member according to Example 3, in the conductive film, a path that linearly connected the pair of electrode pads in the first direction D1 was present between two non-conductive portions. Therefore, it is considered that a portion where the current density locally increases and a portion where the current density locally decreases are likely to occur, and the temperature distribution of the conductive film is likely to be non-uniform.

Next, Table 3 below shows the results of the visibility evaluation for Examples 1 to 6.

TABLE 3

| | | Visibility |
|---|---|---|
| | Dummy Wiring | Evaluation |
| Example 1 | Not Present | B |
| Example 2 | Present | A |
| Example 3 | Not Present | B |
| Example 4 | Not Present | B |
| Example 5 | Not Present | B |
| Example 6 | Not Present | B |

In the conductive member according to Example 2, the result of the visibility evaluation was A. In the conductive members according to Examples 1 and 3 to 6, the results of the visibility evaluation were B.

In the conductive member according to Example 2, the plurality of dummy wirings were disposed in the non-conductive portion. Therefore, it is considered that the presence of the non-conductive portion is inconspicuous.

In addition, in the conductive members according to Examples 1 and 3 to 6, the dummy wirings were not formed. Therefore, it is considered that the presence of the non-conductive portion is likely to be relatively conspicuous.

Basically, the present invention is configured as described above. Hereinabove, the conductive member according to the embodiment of the present invention has been described in detail. However, the present invention is not limited to the above-described examples, and various improvements or modifications can be made within a range not departing from the scope of the present invention.

### EXPLANATION OF REFERENCES

11, 61: conductive member
12: substrate
13, 23: conductive film
14, 24: electrode pad
15: conductive wiring
16, 36, 46, 56, 66, 76: non-conductive portion
17: opening portion
18, 38, 58: edge portion
59: dummy wiring
A1: path
C1, C2, C3, C4, C5, C6, C7: connection point
CL: center line
D1: first direction
D2: second direction
E, P1, P2, Q1, Q2: pitch
F1, F2: line segment
G: gap
K1, K2, K3, K6: distance
L1, L2, L3, W: width
M1, M3, M6: conductive mesh
T: line width
U1, U3, U4, U5, U6, U7: base unit

What is claimed is:

1. A conductive member where a conductive film is formed, the conductive member comprising:
an electrode pad for applying a voltage to the conductive film,
wherein a plurality of non-conductive portions that are arranged to form a regular repeating pattern are formed in the conductive film,
each of the plurality of non-conductive portions includes a plurality of base units having an elongated shape that are connected to each other at a connection point and extend from the connection point in different directions, and
a direction in which a line segment that connects the connection points of two non-conductive portions closest to each other among the plurality of non-conductive portions extends is different from each of the directions in which the plurality of base units extend.

2. The conductive member according to claim 1,
wherein a pair of the electrode pads are connected to both end parts of the conductive film, and
in the conductive film, the non-conductive portion is disposed on any path that connects the pair of electrode pads to each other along a surface of the conductive film.

3. The conductive member according to claim 2,
wherein the conductive film extends in a planar shape, and
the non-conductive portion is disposed on any path that linearly connects the pair of electrode pads to each other along the surface of the conductive film.

4. The conductive member according to claim 1,
wherein the non-conductive portion is configured by four base units, and
the four base units are connected to each other to form a cross shape at the connection point.

5. The conductive member according to claim 2,
wherein the non-conductive portion is configured by four base units, and
the four base units are connected to each other to form a cross shape at the connection point.

6. The conductive member according to claim 3,
wherein the non-conductive portion is configured by four base units, and
the four base units are connected to each other to form a cross shape at the connection point.

7. The conductive member according to claim 4,
wherein a distance between the two non-conductive portions closest to each other among the plurality of non-conductive portions is 20% or more and 50% or less with respect to a distance between the connection points of the two non-conductive portions.

8. The conductive member according to claim 5,
wherein the distance between the two non-conductive portions closest to each other among the plurality of non-conductive portions is 30% or more and 40% or less with respect to the distance between the connection points of the two non-conductive portions.

9. The conductive member according to claim 1, further comprising:
a plurality of conductive wirings that form a mesh shape,
wherein the conductive film is formed of the plurality of conductive wirings.

10. The conductive member according to claim 2, further comprising:
a plurality of conductive wirings that form a mesh shape,
wherein the conductive film is formed of the plurality of conductive wirings.

11. The conductive member according to claim 3, further comprising:
a plurality of conductive wirings that form a mesh shape,
wherein the conductive film is formed of the plurality of conductive wirings.

12. The conductive member according to claim 9,
wherein a direction in which at least one of the base units of the non-conductive portion extends is the same as one of directions in which the plurality of conductive wirings extend.

13. The conductive member according to claim 9,
wherein the directions in which the plurality of base units of the non-conductive portion extend are different from directions in which the plurality of conductive wirings extend.

14. The conductive member according to claim 9,
wherein the electrode pad has a width that is 10 or more times wider than a line width of the conductive wiring.

15. The conductive member according to claim 9, further comprising:
a plurality of dummy wirings that are disposed on extension lines of the plurality of conductive wirings and are electrically insulated from the plurality of conductive wirings in the non-conductive portion.

16. The conductive member according to claim 1,
wherein the conductive film has a shape along a curved surface.

17. The conductive member according to claim 1,
wherein the conductive film has a sheet resistance of 0.1 Ω/□ or more and 10.0 Ω/□ or less.

18. The conductive member according to claim 17,
wherein the conductive film has a sheet resistance of 0.3 Ω/□ or more and 3.0 Ω/□ or less.

19. The conductive member according to claim 1,
wherein the base unit has a width of 0.1 mm or more and 1000.0 mm or less in a direction in which the base unit extends.

20. A heater comprising:
the conductive member according to claim 1.
